(19) United States
(12) Patent Application Publication
(10) Pub. No.: US 2015/0138697 A1
(43) Pub. Date: May 21, 2015

(54) Protective Cover for an Electronic Device and Method of Manufacturing the Same

(71) Applicant: NVIDIA CORPORATION, SANTA CLARA, CA (US)

(72) Inventors: Siarhei Murauyou, Santa Clara, CA (US); Tommy Lee, Santa Clara, CA (US); Glenn Wernig, Santa Clara, CA (US); Khashayar Anoosheh, Santa Clara, CA (US); Nelson Au, Santa Clara, CA (US)

(73) Assignee: NVIDIA CORPORATION, SANTA CLARA, CA (US)

(21) Appl. No.: 14/286,697

(22) Filed: May 23, 2014

Related U.S. Application Data
(60) Provisional application No. 61/907,331, filed on Nov. 21, 2013.

(51) Int. Cl. H05K 5/03

(52) U.S. Cl. CPC H05K 5/03
USPC 361/679.01

(57) ABSTRACT

Provided for herein is a protection device for an electronic device, comprising (1) a cover having a cover width, cover height and cover thickness; and (2) a spindle attached to an edge of the cover, the spindle configured to cooperatively engage a groove formed in a housing of the electronic device and couple the cover to the electronic device.

### CROSS-REFERENCE TO RELATED APPLICATION

This application claims the benefit of U.S. Provisional Application Ser. No. 61/907,331, filed by Siarhei Murauyou, et al. on Nov. 21, 2013, entitled “TABLET SOFT COVER AND STAND,” commonly assigned with this application and incorporated herein by reference.

### TECHNICAL FIELD

This application is directed, in general, to a cover for an electronic device and, more specifically, to a hinged cover for an electronic device.

### BACKGROUND

Glass screens of tablet computers, cellular phones and similar electronic devices can be broken or cracked when dropped or subjected to other unexpected forces. These devices are expensive to replace. Accordingly, most owners of such devices invest in some type of protective mechanism to shield the screens from potential damage. Described herein is a protective device for an electronic device that provides protection as well as other functions.

### SUMMARY

One aspect provides for a protection device for an electronic device, comprising (1) a cover having a cover width, cover height and cover thickness; and (2) a spindle attached to an edge of the cover, the spindle configured to cooperatively engage a groove formed in a housing of the electronic device and couple the cover to the electronic device. Another aspect provides a method of manufacturing a protection device for an electronic device.

Still another aspect provides for an electronic device. The electronic device, in this embodiment, includes: (1) a housing having a housing width, housing height, housing thickness, and a front and a back, (2) a display positioned proximate the front of the housing; (3) a magnetic or ferromagnetic rail positioned proximate the back of the housing, the magnetic or ferromagnetic rail configured to assist in providing multiple viewing angles for the electronic device; (4) a protection device coupled to the housing, the protection device including: (i) a cover having a cover width, cover height and cover thickness, wherein the cover is divided into at least three segments hinged together by bend points substantially paralleling the cover height, and (ii) a spindle attached to an edge of said cover, said spindle configured to cooperatively engage a groove formed in the housing.

### BRIEF DESCRIPTION

Reference is now made to the following descriptions taken in conjunction with the accompanying drawings, in which:

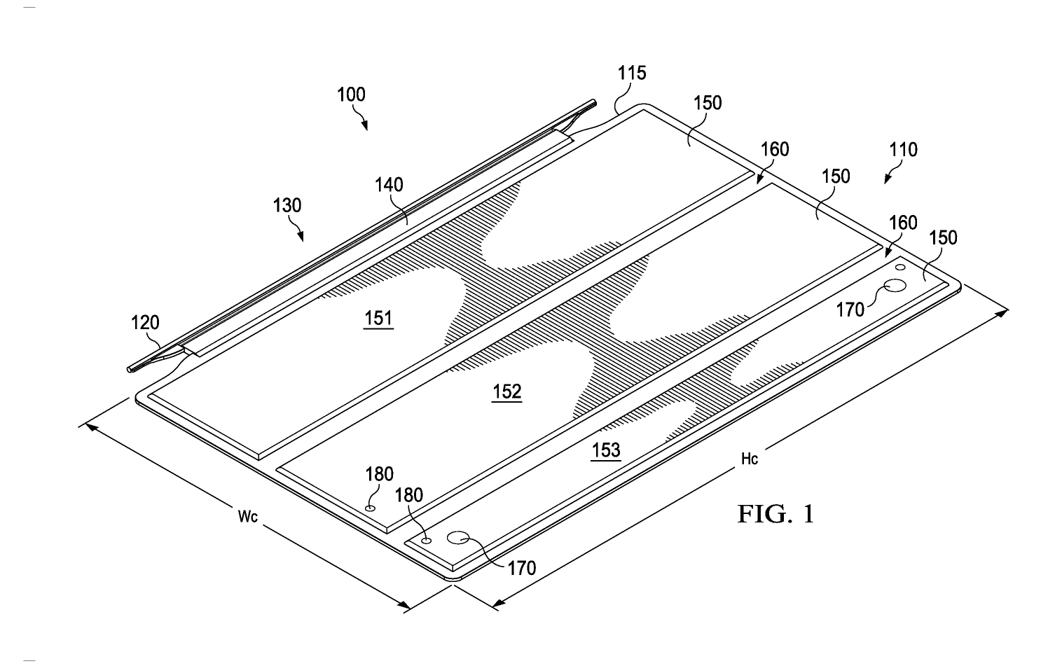

FIG. 1 is an isometric top view of a protection device for an electronic device, as described herein;

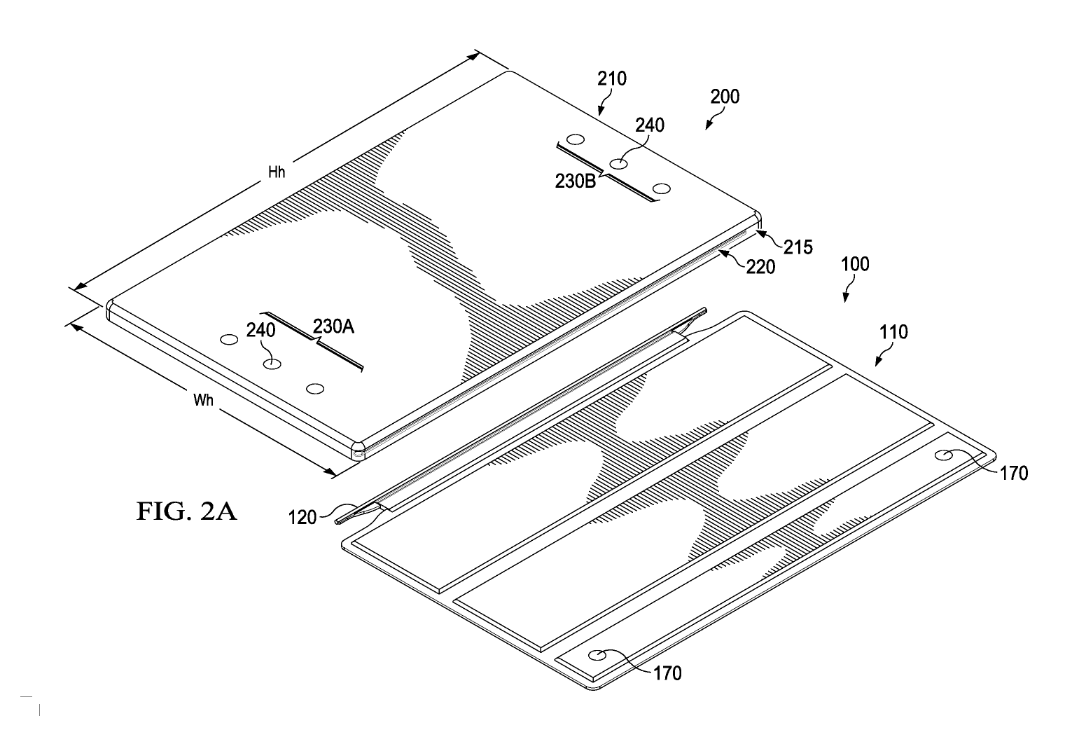

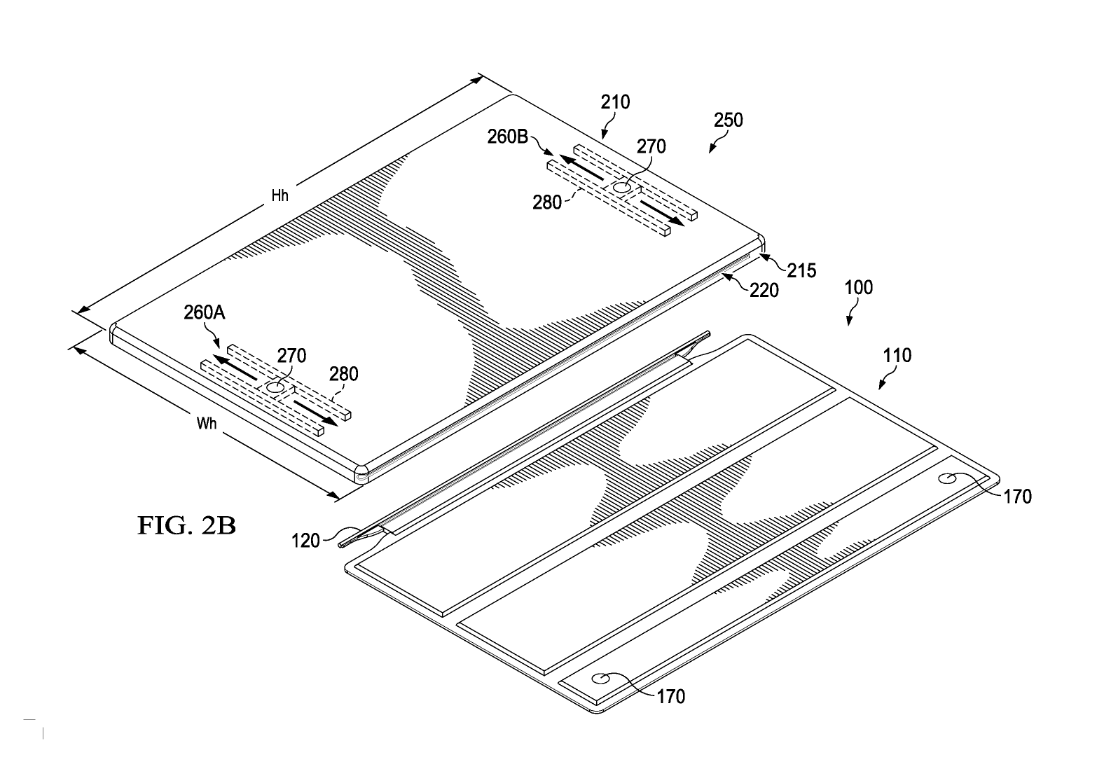

FIGS. 2A and 2B illustrate isometric top views of different embodiments of a protection device and an electronic device to be protected;

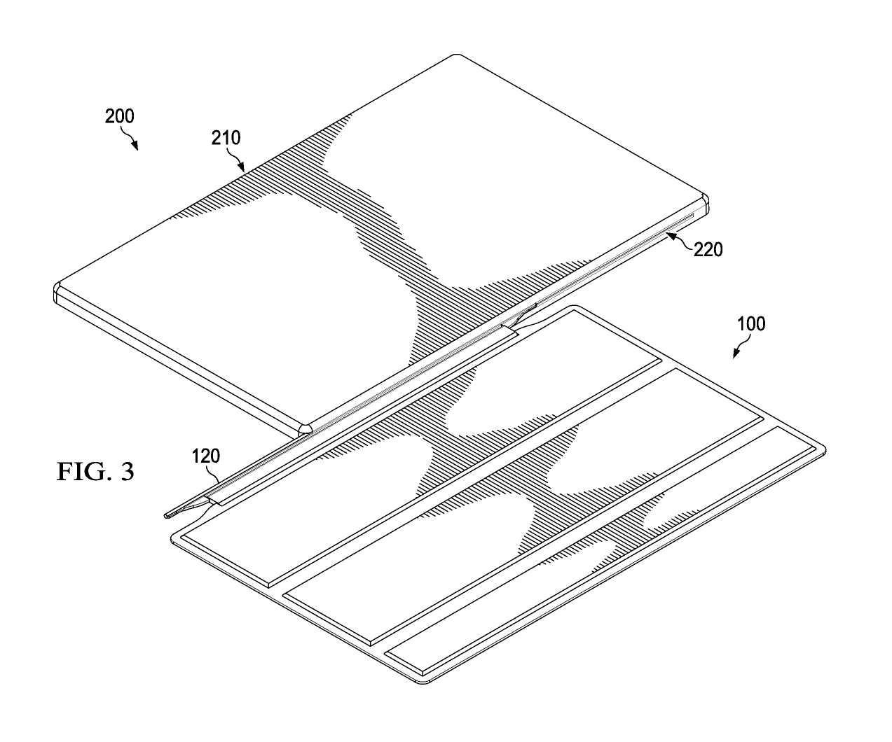

FIG. 3 is an isometric view of a protection device in the process of being attached to an electronic device, showing the spindle as it is being inserted into a groove formed in the housing of the electronic device;

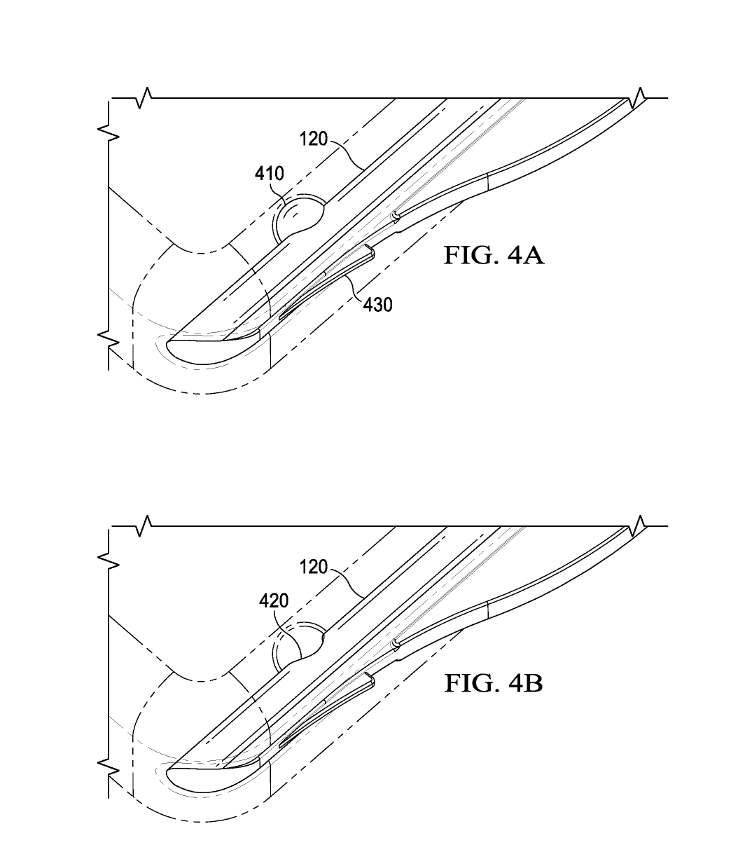

FIGS. 4A and 4B illustrate planar top views of specific portions of the spindle;

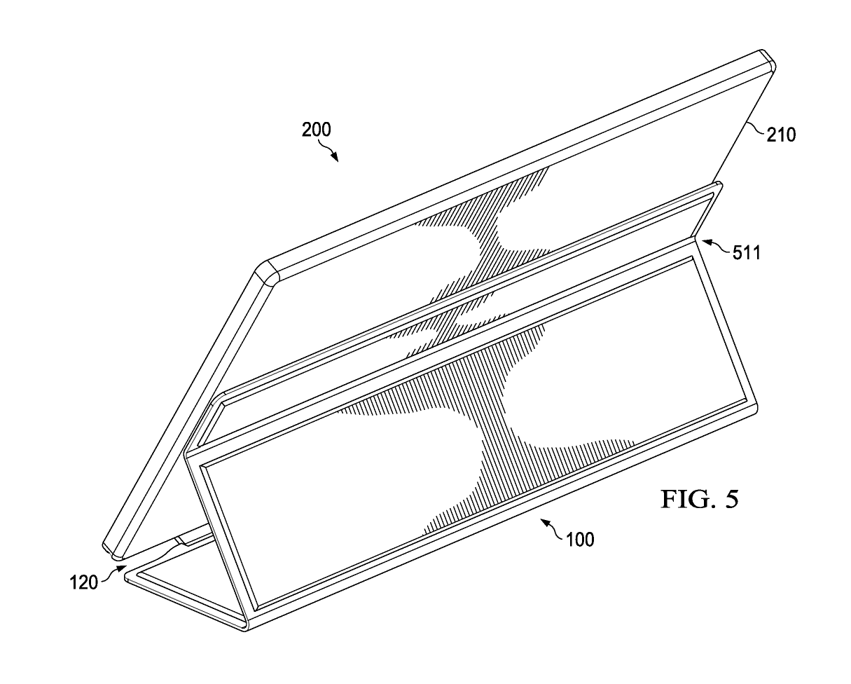

FIG. 5 is an isometric view of one embodiment of a protection device in use as a support structure for holding an electronic device in a viewing position;

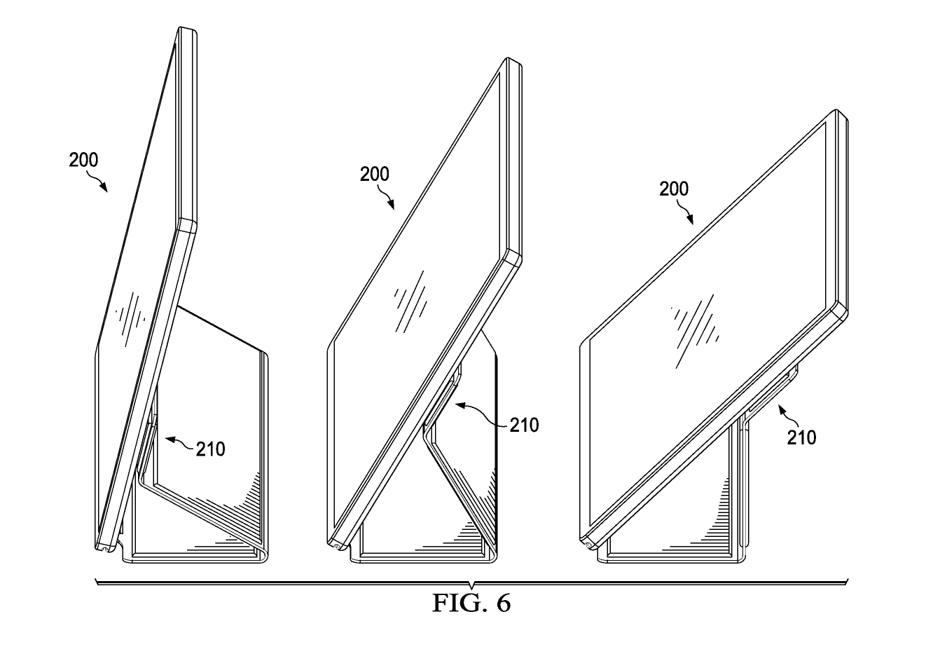

FIG. 6 shows isometric views of three viewing positions for an electronic device; and

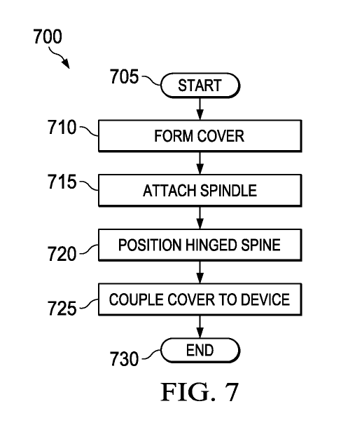

FIG. 7 is a flow chart of one embodiment of a method of manufacturing a protective device for an electronic device.

### DETAILED DESCRIPTION

FIG. 1 is an isometric top view of a protection device 100 for an electronic device, as described herein. The illustrated protection device 100 includes a cover 110 having a cover width (W_{c}), cover height (H_{c}) and cover thickness (T_{c}). The cover 110 can be of any material providing suitable protection for an electronic device, particularly an electronic device that has a breakable (e.g., glass) display. As known to those skilled in the relevant art, there are a number of rigid and semi-rigid materials suitable for such purposes. A particularly useful embodiment is constructed of a semi-rigid protective flexible material that results in a cover 110 known in the relevant art as a “soft cover”.

In the embodiment of FIG. 1, attached to an edge 115 of the cover height (H_{c}) of the cover 110 is a spindle 120. In this embodiment, the cover 110 and the spindle 120 hinge with respect to one another. For example, in the illustrated embodiment of FIG. 1, a double pin hinge 130 couples the cover 110 to the spindle 120. The double pin hinge 130, in accordance with this embodiment, employs a spine 140 that uses an edge of the cover 110 as one pin and a portion of the spindle 120 as another pin. The illustrated double pin hinge 130 is configured to allow the cover 110 to pivot with respect to an associated electronic device via the spine 140. The double pin hinge 130 permits the cover 110 and spindle 120 to independently pivot about the spine 140, and therefore independently pivot with respect to each other.

In accordance with one embodiment, the spine 140 has a width that permits the cover 110 to lie flat against the electronic device when the cover 110 is shut, as well as lie flat against the electronic device when it is completely open. Because the protective device 100 can be used to protect a variety of electronic devices of different thickness, the width of the spine 140 may vary.

In the embodiment of FIG. 1, the cover 110 is divided into a plurality of segments 150 hinged together by bend points 160. Further to the embodiment shown, the bend points 160 substantially parallel the cover height (H_{c}), and thus the spindle 120. In one embodiment, the plurality of segments 150 is three segments 151, 152, 153. As will be detailed further below, this configuration permits the cover 110 to be used as a supporting structure for holding an electronic device in a specific viewing position when set on a surface. The illustrated embodiment has the two segments 151, 152 nearest the spindle 120 about equal in size, whereas the third segment 153 is less than about one half the size of either of the other two. This ratio of segment 150 sizes, or at least the idea of a smaller third segment 153, provides a beneficial supporting structure for holding certain electronic devices in various viewing positions. Nevertheless, other ratios and sizes may be desirable for other types of electronic devices.

The protection device 100 of the embodiment of FIG. 1 further includes one or more magnetic or ferromagnetic cover elements 170 incorporated in or on the cover 110. In accordance with the disclosure, the one or more magnetic or ferromagnetic cover elements 170, depending on the type of magnetic or ferromagnetic rail elements that they are configured to mate with, may comprise non-magnetized ferromagnetic materials that are attracted to other magnets, ferromagnetic materials that are (e.g., permanently) magnetized, or ferroelectric materials that are magnetized by the application of an external electric field. As will be further understood below, the one or more magnetic or ferromagnetic cover elements 170 assist in holding an electronic device attached to the protection device 100 in various different viewing positions.

The embodiment of FIG. 1 embodies two magnetic or ferromagnetic cover elements 170 located proximate opposing edges of the cover width (W_{c}) of the outer third segment 153. Other embodiments, however, exist wherein more or less than two magnetic or ferromagnetic cover elements 170 are used. Additionally, the two magnetic or ferromagnetic cover elements 170 must not always be placed on or in the outer segment 153, and might be located in other regions of the cover 110, including other locations relative to the edges of the segments 150. Yet other embodiments exist wherein a single magnetic or ferromagnetic cover element 170 is used (not shown), for example located proximate a centerpoint of the cover height (HJ of the outer third segment 153.

The protection device 100 of the embodiment of FIG. 1 might further include one or more magnetic or ferromagnetic closure elements 180 configured to hold the cover closed over the face of the electronic device. The one or more magnetic or ferromagnetic closure elements 180 may additionally have the benefit of being used to waking up, or make sleep, the electronic device where appropriate. Those skilled in the art understand the idea and implementation of using the one or more magnetic or ferromagnetic closure elements 180 for the above-discussed purposes.

Turning to FIG. 2A, illustrated is an isometric top view of the protection device 100 of FIG. 1 and of an electronic device 200 to be protected. Use of the protection device 100 is not limited to a tablet computer 200 as illustrated. It can also be used on other electronic devices 200 having a similar construction, such as cellular telephones and personal electronic devices, among others. The electronic device 200 of the embodiment of FIG. 2A has a housing 210 having a housing width (Wₕ), housing height (Hₕ) and a housing thickness (Tₕ). Formed in an edge 215 of the housing 210 is a groove 220. In the particular embodiment shown, the groove 220 is formed in the edge 215 of the housing height (Hₕ) of the housing 210. The groove 220, in accordance with the disclosure, is configured to cooperatively engage with the spindle 120, and thus couple the cover 110 to the electronic device 200.

The groove 220, in the particular embodiment of FIG. 2A, substantially extends along a length of an edge (e.g., the edge 215) of the housing 220. In one embodiment, the groove 220 extends over at least about 50% the length of the edge 215. In another embodiment, the groove 220 extends over at least about 75% the length of the edge 215. The groove 220, and spindle 120, in one particular embodiment have shapes that substantially complement each other to provide a snug (e.g., friction forming) fit.

To provide for the possibility of multiple viewing positions, a magnetic or ferromagnetic rail 230 may be positioned proximate the back of the electronic device 200. In certain embodiments, the magnetic or ferromagnetic rail 230 is integral to the housing 210. In other embodiments, the magnetic or ferromagnetic rail 230 is attached to the back of the housing 210. In yet other embodiments, the magnetic or ferromagnetic rail 230 is integral with a protection device attached to the back of the housing 210.

The magnetic or ferromagnetic rail 230, in accordance with one embodiment, is substantially parallel the housing width (Wₕ). In accordance with one embodiment of the disclosure, such as shown, two or more magnetic or ferromagnetic rails 230A, 230B are positioned on opposing edges of the electronic device 200 and substantially parallel the housing width (Wₕ).

In the embodiment of FIG. 2A, the two or more magnetic or ferromagnetic rails 230A, 230B each comprise two or more (in this embodiment three) linearly spaced magnetic or ferromagnetic rail elements 240. In accordance with one embodiment, such as that shown, the linearly spaced magnetic or ferromagnetic rail elements 240 are also placed substantially parallel with the housing width (Wₕ). The magnetic or ferromagnetic rails 230, and thus the linearly spaced magnetic or ferromagnetic rail elements 240, in accordance with the disclosure, are configured to magnetically attach to the magnetic or ferromagnetic cover elements 170 to form multiple viewing angles for the electronic device 200. As the user desires for a different viewing angle, the user could attach the magnetic or ferromagnetic cover elements 170 to other associated ones of the linearly spaced magnetic or ferromagnetic rail elements 240. If each of the magnetic or ferromagnetic rails 230A, 230B included three linearly spaced magnetic or ferromagnetic rail elements 240, three different viewing angles would be attainable. In accordance with one embodiment of the disclosure, anywhere from one to twenty different linearly spaced magnetic or ferromagnetic rail elements 240 could be used for each magnetic or ferromagnetic rail 230, thereby providing from one to twenty different viewing angles for the electronic device 200. Ideally, however, five or less, and more particularly two to four, different linearly spaced magnetic or ferromagnetic rail elements 240 could be used for each magnetic or ferromagnetic rail 230, thus providing for five or less (e.g., two to four) different viewing angles.

Turning briefly to FIG. 2B, illustrated is an isometric top view of the protection device 100 of FIG. 1 and of an alternative electronic device 250 to be protected. In this alternative embodiment, the electronic device 250 includes one or more magnetic or ferromagnetic rails 260 (e.g., two magnetic or ferromagnetic rails 260A, 260B), but each of the one or more magnetic or ferromagnetic rails includes one magnetic or ferromagnetic rail element 270 that slides linearly within its associated magnetic or ferromagnetic rail 260 to provide multiple viewing angles for the electronic device 250. In the particular embodiment shown, the magnetic or ferromagnetic rail elements 270 slide linearly substantially paralleling the housing width (Wₕ).

In the embodiment of FIG. 2B, the magnetic or ferromagnetic rail elements 270 might be configured to move to different positions along the back of the electronic device 250. For example, the electronic device 250 might have preset locations for the magnetic or ferromagnetic rail elements 270 to gravitate (e.g., snap or otherwise settle) toward. In one embodiment, the magnetic or ferromagnetic rail elements 270 would gravitate to three different positions, for example similar to the positions of the magnetic or ferromagnetic rail elements 240 illustrated in FIG. 2A. Alternatively, the magnetic or ferromagnetic rail elements 270 would slide along supports 280, and thus provide essentially an unlimited number of different viewing angels for the electronic device 200, but easily at least 10 significantly different viewing angles. Those skilled in the art understand the steps that would be necessary to implement these additional embodiments, including possible requiring the magnetic or ferromagnetic rail elements 260 to move in unison.

Turning to FIG. 3, illustrated is a planar isometric view of the protection device 100 in the process of being attached to the electronic device 200. In this configuration, the spindle 120 is partially inserted in the groove 220 formed in the housing 210. As is understood, when the spindle 120 is completely inserted in the groove 220, the cover 110 is coupled to the electronic device 200. In one embodiment, friction secures the spindle 120 within the groove 220. In other embodiments, locking structures secure the spindle 120 within the groove 220. The locking structures may comprise a variety of different configurations and remain within the purview of the disclosure.

Turning briefly to FIG. 4A, illustrated is a planar top view of a portion of the spindle 120 showing a locking lug 410 for securing the protection device 100 to the electronic device 200. When completely inserted in the groove 220, the locking lug 410 will cooperatively engage an opposing locking notch in the groove 220, and secure the spindle 120 in the groove 220. In one embodiment, the spindle 120 is releasable from the groove 220 because the locking lug 410 has a spring holding the locking lug 410 in the locking notch of the groove 220. In another embodiment the spindle 120 is constructed using a spring-like material that yields when pressure is applied to a release notch 430 on the spindle 120 that forces the locking lug 410 out of the locking notch of the groove 220.

Turning briefly to FIG. 4B, illustrated is planar top view of a portion of the spindle 120 showing a locking notch 420 for securing the protection device 100 to the electronic device 200. In the embodiment wherein the spindle 120 has the locking notch 420, the groove 220 of the electronic device 200 might have an associated locking lug. When the spindle 120 is completely inserted in the groove 220, the locking notch 420 would cooperatively engage the locking lug of the groove 220, and thereby secure the spindle 120 to the electronic device 200.

Returning to FIG. 3, in one embodiment the spindle 120 provides electrical connectivity between the cover 110 and the electronic device 200. For example, associated electrical contacts or traces on the spindle 120 and in the groove 220 might provide the electrical connectivity. The electrical contacts may be connected to corresponding electrical connections on the cover 110 (e.g., via appropriate electrical connections) and the electronic device 200. This permits a keyboard, modem or other similar device to be included as part of the cover 100, and thus electrically connect to the electronic device 200.

Turning to FIG. 5, with continued reference to FIGS. 1 and 2A-2B, illustrated is an isometric view of one embodiment of the protection device 100 in use as a support structure for holding the electronic device 200 in a viewing position. In the illustrated embodiment, magnetic or ferromagnetic cover elements 170 in or on the protection device 100 align with associated magnetic or ferromagnetic rail elements 240, 260 in or on the housing 210. Accordingly, the magnetic elements or ferromagnetic cover elements 170 in or on the protection device 100 and associated magnetic or ferromagnetic rail elements 240, 260 in or on the housing 210 cooperate to form a triangular structure that holds the electronic device 200 in a viewing position. Thus, when the cover 110 is swiveled and folded at each of the bend points 160, the segment 153 most distant from the spindle 120 is magnetically attached to the back of the electronic device 200 and a triangular structure is formed to support the electronic device 200 at a viewing angle. Those skilled in the art understand the process for placement of the magnetic or ferromagnetic cover elements 170 and associated magnetic or ferromagnetic rail elements 240, 260 in or on the housing 210.

Illustrated in FIG. 6 are isometric views of multiple viewing positions for the electronic device 200. The different views illustrated in FIG. 6 correspond to the placement of magnetic and ferromagnetic cover elements 170 on or in the cover 110 and the associated magnetic or ferromagnetic rail elements 240, 260 on or in the electronic device 200. For example, as there are three pairs of magnetic or ferromagnetic rail elements illustrated in FIG. 2A, each of which is configured to couple to the pair of magnetic or ferromagnetic cover elements 170, three different viewing positions are illustrated as possible. Those skilled in the art, however, understand that other embodiments may exist wherein more, or less, than three viewing positions are possible, including the scenario illustrated in FIG. 2B.

Turning now to FIG. 7, illustrated is a flow chart of an embodiment of a method of manufacturing 700 a protective device for an electronic device. The method 700 commences with a start step 705. In a form cover step 710, a cover having a cover width (W_{c}), cover height (H_{c}) and thickness (T_{c}) is formed. In an attach spindle step 715, a spindle configured to cooperatively engage a groove formed in a housing of an electronic device is attached to an edge of the cover. In a position hinged spine step 720, a hinged spine is located between the cover and the spindle, and the hinged spine is configured to allow the cover and the spindle to pivot with respect to one another. In a couple cover to device step 725, the spindle is inserted in a groove on the housing of the electronic device. In one embodiment the spindle is releasable from the groove. In another embodiment, the hinged spine is constructed to provide electrical connectivity between the cover and the electronic device, which permits a modem or keyboard to be used as a cover. Some embodiments use a double pin hinge as a hinged spine in order to permit pivoting with respect to each pin on the hinge.

In one embodiment the cover is formed with a plurality of segments hinged together by bend points paralleling the spindle. In one embodiment there are three segments with the segment furthest from the spindle less than about half the size of each of the other two segments. In another embodiment, the cover includes a pair of magnetic or ferromagnetic cover elements integral therewith in order to attach to pairs of associated magnetic or ferromagnetic rail elements on the back of the electronic device. In one embodiment, this attachment forms a triangular shape for supporting the electronic device in a viewing position. One embodiment calls for the installation of three pairs of associated magnetic or ferromagnetic rail elements on or in the back of the electronic device to provide three different viewing positions. The method concludes with an end step 730.

Those skilled in the art to which this application relates will appreciate that other and further additions, deletions, substitutions and modifications may be made to the described embodiments.

What is claimed is:

1. A protection device for an electronic device, comprising:
a cover having a cover width, cover height and cover thickness; and
a spindle attached to an edge of said cover, said spindle configured to cooperatively engage a groove formed in a housing of said electronic device and couple said cover to said electronic device.

2. The protection device as recited in claim 1, further including a hinged spine positioned between said cover and said spindle, said hinged spine configured to allow said cover and said electronic device to pivot with respect to one another.

3. The protection device as recited in claim 2, wherein said spindle provides an electrical connection between said cover and said electronic device via electrical contacts.

4. The protection device as recited in claim 2, wherein said cover includes a modem.

5. The protection device as recited in claim 2, wherein said cover includes a keyboard.

6. The protection device as recited in claim 2, wherein said hinged spine is a double pin hinge with a portion of said spindle serving as one pin of said double pin hinge.

7. The protection device as recited in claim 6, wherein said hinged spine is constructed to allow said cover and said electronic device to each pivot with respect to said double pin hinge.

8. The protection device as recited in claim 6, wherein said hinged spine has a width permitting said cover, when closed, to lie substantially flat against a face of said electronic device or, when open, to lie substantially flat against a back of said electronic device.

9. The protection device as recited in claim 1, wherein said spindle has a locking lug or a locking notch capable of cooperatively engaging a corresponding locking notch or locking lug on said electronic device to secure said spindle in said groove.

10. The protection device as recited in claim 9, wherein said spindle is releasable from said groove.

11. The protection device as recited in claim 1, wherein said cover is divided into a plurality of segments hinged together by bend points substantially paralleling said spindle.

12. The protection device as recited in claim 11, wherein said plurality of segments is three.

13. The protection device as recited in claim 12, wherein said two segments nearest said spindle are about equal in size and said third segment is less than about one-half the size of each of the other two segments.

14. The protection device as recited in claim 13, wherein said cover includes one or more magnetic or ferromagnetic cover elements.

15. The protection device as recited in claim 14, wherein said cover includes two magnetic or ferromagnetic cover elements located at opposing sides of said third segment.

16. The protection device as recited in claim 15, wherein said two magnetic or ferromagnetic cover elements are configured to magnetically attach to two associated magnetic or ferromagnetic rails located on a back of said electronic device when said cover is swiveled open.

17. The protection device as recited in claim 16, wherein said back of said electronic device includes two magnetic or ferromagnetic rails, said two magnetic or ferromagnetic rails being separated along a dimension perpendicular to an edge of the electronic device including the groove, said two magnetic or ferromagnetic cover elements configured to magnetically attach to said two magnetic or ferromagnetic rails thereby forming a plurality of viewing positions for said electronic device.

18. The protection device as recited in claim 17, wherein each of said magnetic or ferromagnetic rails includes three or more magnetic or ferromagnetic rail elements, thereby forming three or more different viewing positions for said electronic device.

19. An electronic device, comprising:
a housing having a housing width, housing height, housing thickness, and a front and a back;
a display positioned proximate the front of the housing;
a magnetic or ferromagnetic rail positioned proximate the back of the housing, the magnetic or ferromagnetic rail configured to assist in providing multiple viewing angles for the electronic device;
a protection device coupled to the housing, the protection device including;
a cover having a cover width, cover height and cover thickness, wherein the cover is divided into at least three segments hinged together by bend points substantially paralleling the cover height; and
a spindle attached to an edge of said cover, said spindle configured to cooperatively engage a groove formed in the housing.

20. The electronic device of claim 19, wherein the cover includes a magnetic or ferromagnetic cover element coupled to one of the at least three segments, the magnetic or ferromagnetic cover element configured to magnetically attach to magnetic or ferromagnetic rails, and thereby provide multiple viewing angles for the electronic device.
